(19) United States
(12) Patent Application Publication
(10) Pub. No.: US 2026/0150276 A1
(43) Pub. Date: May 28, 2026

(54) SEMICONDUCTOR STRUCTURE AND METHOD FOR FORMING THE SAME

(71) Applicant: Winbond Electronics Corp., Taichung City (TW)

(72) Inventors: Wen-Chia OU, Kaohsiung City (TW); Yu-Feng CHENG, Taichung City (TW)

(21) Appl. No.: 19/395,345

(22) Filed: Nov. 20, 2025

(30) Foreign Application Priority Data
Nov. 27, 2024 (TW) 113145647

(51) Int. Cl. H10B 12/00; H01L 21/762

(52) U.S. Cl. CPC H10B 12/50; H10B 12/09; H10B 12/34; H10W 10/0143; H10W 10/17

(57) ABSTRACT

A semiconductor structure and a method for forming the same are provided. The semiconductor structure includes a substrate, an isolation feature, and a first-type component. The isolation feature is disposed in a trench adjacent to a peripheral region of the substrate. The isolation feature includes first to third liners and a filling layer. The first liner covers a sidewall of the trench adjacent to the peripheral region. The second liner covers the first liner and a lower portion of the sidewall. The third liner covers the exposed first liner. The filling layer fills the trench. In a direction perpendicular to the top surface of the substrate, a first bottom surface of a first source/drain region of the first-type component in the peripheral region is located between the top surface of the substrate and a second bottom surface of the third liner.

### CROSS REFERENCE TO RELATED APPLICATIONS

This application claims priority of Taiwan patent application No. 113145647, filed on Nov. 27, 2024, the entirety of which is incorporated by reference herein.

### BACKGROUND OF THE DISCLOSURE

### Field of the Disclosure

The present disclosure relates to a semiconductor structure and a method for forming the same, and, in particular, it relates to an isolation feature of a semiconductor structure and a method for forming the same.

### Description of the Related Art

The semiconductor manufacturing technology continues to work towards the miniaturization of component sizes, however, this gives rise to many challenges in the effort to increase the density of components in semiconductors and improve their overall performance. For example, when the channel length of a transistor continues to shrink, the threshold voltage roll-off (Vt roll-off) phenomenon of the component demands further improvements.

### BRIEF SUMMARY OF THE INVENTION

An embodiment of the present disclosure provides a semiconductor structure. The semiconductor structure includes a substrate, a first isolation feature, and a first-type component. The substrate has a first peripheral region. The first isolation feature is disposed in a first trench of the substrate adjacent to the first peripheral region. The first trench has a first sidewall adjacent the first peripheral region. The first isolation feature includes a first liner, a second liner, a third liner, and a filling layer. The first liner conformally covers the first sidewall of the first trench. The second liner conformally covers the first liner and covers a lower portion of the first sidewall so that a portion of the first liner is exposed from the second liner. The third liner conformally covers the portion of the first liner exposed from the second liner. The filling layer fills the first trench and covers the second liner and the third liner. The first-type component is formed in the first peripheral region. In a direction substantially perpendicular to the top surface of the substrate, a first bottom surface of a first source/drain region of the first-type component is located between the top surface of the substrate and a second bottom surface of the third liner.

An embodiment of the present disclosure provides a method for forming a semiconductor structure. The method includes providing a substrate having a first peripheral region. The method further includes forming a first trench in the substrate adjacent to the first peripheral region. The first trench has a first sidewall adjacent to the first peripheral region. The method further includes forming a first isolation feature in the first trench. The first isolation feature includes a first liner, a second liner, a third liner and a filling layer. The first liner conformally covers the first sidewall of the first trench. The second liner conformally covers the first liner and covers a lower portion of the first sidewall, so that a portion of the first liner is exposed from the second liner. The third liner conformally covers the portion of the first liner exposed from the second liner. The filling layer fills the first trench and covers the second liner and the third liner. The method further includes forming a first-type component in the first peripheral region. In a direction substantially perpendicular to a top surface of the substrate, a first bottom surface of a first source/drain region of the first-type component is located between the top surface of the substrate and a second bottom surface of the third liner.

### BRIEF DESCRIPTION OF THE DRAWINGS

FIG. 1 is a schematic cross-sectional view of a semiconductor structure in accordance with some embodiments of the disclosure; and

FIGS. 2, 3, 4, 5, 6, 7, 8, and 9 are schematic cross-sectional views of intermediate stages of forming the semiconductor structure shown in FIG. 1 in accordance with some embodiments of the disclosure.

### DETAILED DESCRIPTION OF THE INVENTION

When the component size of conventional integrated circuit devices having complementary metal-oxide-semiconductor field effect transistors shrinks, the N-type metal-oxide-semiconductor field effect transistor (N-type MOSFET) device will produce a short channel effect due to the continuous shrinkage of the channel length, which may cause the Vt roll-off phenomenon of the component, while the P-type metal-oxide semiconductor field-effect transistor (P-type MOSFET) device does not have this phenomenon. In order to solve the aforementioned problems, the semiconductor structure in accordance with some embodiments of the disclosure creates a locally deformed element region of the N-type MOSFET by changing the material of a portion of the liners of the isolation feature, thereby increasing the electron mobility in the channel region of the N-type MOSFET, and suppressing the Vt roll-off phenomenon of the N-type MOSFET. Since the semiconductor structure in accordance with some embodiments of the disclosure has specific stress only in the designated component region without affecting the electrical performances of electronic components in other component regions.

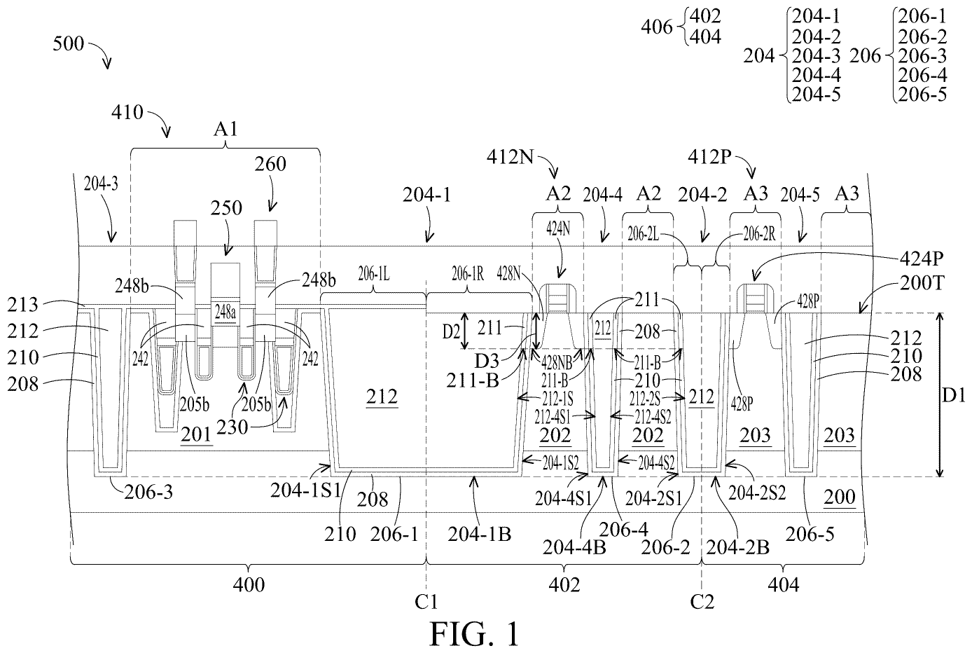

Referring to FIG. 1, a semiconductor structure 500 includes a memory array and a peripheral device. The memory array may include a DRAM array or other suitable memory arrays. The peripheral device may include metal-oxide-semiconductor field effect transistors (MOSFETs) or other suitable peripheral devices. The semiconductor structure 500 includes a substrate 200, isolation features 206 (including isolation features 206-1, 206-2, 206-3, 206-4, and 206-5), a first well region 201, a second well region 202, and a third well region 203, active regions A1, A2, and A3, a memory array 410, a first-type component 412N and a second-type component 412P.

The semiconductor structure 500 may have an array region 400 and a peripheral region 406 adjacent to the array region 400. The peripheral region 406 includes a first peripheral region 402 adjacent to the array region 400 and a second peripheral region 404 adjacent to the first peripheral region 402. For example, the array region 400 is provided as the formation area of the memory array 410. The first peripheral region 402 is provided as the formation area of the first-type component 412N. In addition, the second peripheral region 404 is provided as the formation area of the second-type component 412P. In some embodiments, the first-type component 412N and the second-type component 412P have opposite conductivity types. For example, the first-type component 412N is an N-type MOSFET, and the second-type component 412P is a P-type MOSFET.

The substrate 200 may be an element semiconductor substrate, such as a silicon substrate or a germanium substrate; or a compound semiconductor substrate, such as a silicon carbide substrate or a gallium arsenide substrate. In some embodiments, the substrate 200 may be a semiconductor-on-insulator (SOI) substrate. In some embodiments, the conductivity type of the substrate 200 may be P-type or N-type according to design requirements.

The semiconductor structure 500 may include a first well region 201, a second well region 202 and a third well region 203 located in the substrate 200. The first well region 201 is located in the array region 400, the second well region 202 is located in the first peripheral region 402, and the third well region 203 is located in the second peripheral region 404. In some embodiments, the first well region 201 and the second well region 202 may have the same conductivity type and doping concentration. The first well region 201 (or the second well region 202) and the third well region 203 may have opposite conductivity types.

Isolation features 206 are disposed in corresponding trenches 204 (including trenches 204-1, 204-2, 204-3, 204-4, and 204-5) of the substrate 200. The isolation features 206 may define the active regions A1, A2, and A3 of the array region 400, the first peripheral region 402, and the second peripheral region 404. Moreover, the isolation feature 206 disposed in the array region 400, the first peripheral region 402 or the second peripheral region 404 may be used as an electrical isolation feature for the components formed in the active region A1, A2 or A3. For example, the isolation feature 206-1 is disposed in the trench 204-1 between the array region 400 and the first peripheral region 402. Furthermore, the trench 204-1 has sidewalls 204-1S1, 204-1S2 respectively adjacent to the array region 400 and the first peripheral region 402 and a bottom surface 204-1B. Therefore, the isolation feature 206-1 may define the active region A1 of the array region 400 and the active region A2 of the first peripheral region 402. The isolation feature 206-2 is disposed in the trench 204-2 between the first peripheral region 402 and the second peripheral region 404. Furthermore, the trench 204-2 has sidewalls 204-2S1, 204-2S2 respectively adjacent to the first peripheral region 402 and the second peripheral region 404 and a bottom surface 204-2B. Therefore, the isolation feature 206-2 defines the active region A2 of the first peripheral region 402 and the active region A3 of the second peripheral region 404. The isolation feature 206-3 is disposed in the trench 204-3 in the array region 400 and may be used as an electrical isolation feature for the DRAM formed in the active region A1. The isolation feature 206-4 is disposed in the trench 204-4 in the first peripheral region 402 and may be used as an electrical isolation feature for the N-type MOSFET formed in the active region A2. The isolation feature 206-5 is disposed in the trench 204-5 in the second peripheral region 404 and may be used as an electrical isolation feature for the P-type MOSFET formed in the active region A3. As shown in FIG. 1, the bottom surfaces of the isolation features 206 (including the bottom surfaces 204-1B and 204-2B of the isolation features 206-1 and 206-2) are located below the first well region 201, the second well region 202 and the third well region 203. In some embodiments, any number of the isolation features 206-3, 206-4, and 206-5 may be provided in the array region 400, the first peripheral region 402, and the second peripheral region 404 according to design requirements.

In some embodiments, the isolation feature 206 may be a shallow trench isolation (STI). Each of the isolation features 206-1, 206-2, 206-3, 206-4, and 206-5 may include at least a first liner 208, a second liner 210, and a filling layer 212. In the isolation features 206-1, 206-2, 206-3, 206-4, and 206-5, the first liners 208 may conformally cover the bottom surfaces and opposite sidewalls of trenches 204-1, 204-2, 204-3, 204-4 and 204-5. The second liners 210 may conformally cover the first liners 208. Furthermore, the filling layers 212 may fill the trenches 204-1, 204-2, 204-3, 204-4 and 204-5, and cover the second liner 210.

As shown in FIG. 1, at least one of the differences between the isolation features 206-1 and 206-2 used to define the first peripheral region 402 and the isolation features 206-3 and 206-5 located in the array region 400 and the second peripheral region 404 is that the isolation feature 206-1 has opposite sidewalls (adjacent to the sidewalls 204-1S1, 204-1S2) and a bottom surface (adjacent to the bottom surface 204-1B), and the isolation feature 206-2 has opposite sidewalls (adjacent to the sidewalls 204-2S1, 204-2S2) and a bottom surface (adjacent to the bottom surface 204-2B). The second liners 210 of the isolation features 206-1, 206-2 may completely cover the sidewalls 204-1S1, 204-2S2 and the bottom surfaces 204-1B, 204-2B of the trenches 204-1, 204-2, and extend from the sidewalls 204-1S1 and 204-2S2 to cover the lower portions of the sidewalls 204-1S2 and 204-2S1 (close to the bottom surfaces 204-1B and 204-2B). Therefore, portions of the first liners 208 of the isolation features 206-1 and 206-2 are exposed from the second liners 210. The second liners 210 of the isolation features 206-3, 206-5 may completely cover the opposing sidewalls of the trenches 204-3, 204-5.

At least one of the differences between the isolation feature 206-4 located in the first peripheral region 402 and the isolation features 206-3 and 206-5 located in the array region 400 and the second peripheral region 404 is that the isolation features 206-4 have opposite sidewalls (adjacent to the sidewalls 204-4S1 and 204-4S2) and the bottom surface (adjacent to the bottom surface 204-4B). The second liner 210 of the isolation feature 206-4 extends from the lower portion of the sidewall 204-4S1 (close to the bottom surface 204-4B) to cover the lower portion of the sidewall 204-4S2 (close to the bottom surface 204-4B), so that a portion of the first liner 208 of the isolation feature 206-4 is exposed from the second liner 210.

Moreover, the isolation features 206-1, 206-2 and the isolation feature 206-4 may further include third liners 211. The third liners 211 of the isolation features 206-1, 206-2 are disposed on the sidewalls 204-1S2, 204-2S1 of the trenches 204-1, 204-2 adjacent to the first peripheral region 402. The third liner 211 of the isolation feature 206-4 is disposed on the opposite sidewalls 204-4S1 and 204-4S2 of the trench 204-4. The third liners 211 of the isolation features 206-1, 206-2, 206-4 are located between the first liner 208 and the filling layer 212. In addition, the third liners 211 of the isolation features 206-1, 206-2, 206-4 are arranged side by side with the second liner 210 along the sidewalls 204-1S2, 204-2S1 of the trenches 204-1, 204-2 and the opposite sidewalls 204-4S1 and 204-4S2 of the trench 204-4. Therefore, the interfaces between the second liners 210 and the third liners 211 (the position of the interface is the same as the bottom surfaces 211-B of the third liners 211) are located between the top surface 200T of the substrate 200 and the bottom surfaces 204-1B, 204-2B, and 204-4B of the trenches 204-1, 204-2, and 204-4. The third liners 211 of the isolation features 206-1, 206-2, 206-4 conformally covers the upper portions of the sidewalls 204-1S2, 204-2S1, 204-4S1, 204-4S2 and the first liners 208 exposed from the second liners 210. In some embodiments, the first liner 208, the second liner 210, and the filler layer 212 of each of the isolation features 206-1, 206-2, and 206-4 are in contact with different surfaces of the third liner 211. The different portions of the side surfaces 212-1S, 212-2S, 212-4S1, and 212-4S2 of the filling layers 212 of the isolation features 206-1, 206-2, and 206-4 close to the sidewalls 204-1S2, 204-2S1, 204-4S1, 204-4S2 of trenches 204-1, 204-2, and 204-4 cover and are in contact with the second liners 210 and the third liners 211.

As shown in FIG. 1, the isolation members 206-1 and 206-2 may have a left-right asymmetric structure. For example, the isolation feature 206-1 located between the array region 400 and the first peripheral region 402 is divided into a first half portion 206-1L adjacent to the array region 400 and the second half portion 206-1R adjacent to the first peripheral region 402 along the central axis C1 that is substantially vertical to the top surface 200T of the substrate 200. The first half portion 206-1L and the second half portion 206-1R are asymmetrical to each other along the central axis C1. The isolation feature 206-2 located between the first peripheral region 402 and the second peripheral region 404 is divided into a first half portion 206-2L adjacent to the first peripheral region 402 and the second half portion 206-2R adjacent to the second peripheral region 404 along the central axis C2 that is substantially vertical to the top surface 200T of the substrate 200. The first half portion 206-2L and the second half portion 206-2R are asymmetrical to each other along the central axis C2. In addition, the isolation features 206-3, 206-4, and 206-5 located in the array region 400, the first peripheral region 402, and the second peripheral region 404 may have a left-right symmetrical structure.

In some embodiments, the first liner 208, the second liner 210, the third liner 211 and the filling layer 212 may include insulating materials such as silicon oxide (SiO), silicon nitride (SiN), silicon oxynitride (SiON), and the like, and/or a combination of thereof. In some embodiments, the first liner 208, the third liner 211, and the filling layer 212 are formed of a first material. The second liner 210 is formed of a second material, and the first material is different from the second material. For example, the first liner 208, the third liner 211 and the filling layer 212 may include silicon oxide, and the second liner 210 may include silicon nitride. In some embodiments, the isolation feature 206 is formed using a patterning process followed by a deposition process and a planarization process. The aforementioned patterning process includes a lithography process and an etching process. The aforementioned deposition process includes chemical vapor deposition (CVD) and/or atomic layer deposition (ALD). The aforementioned planarization process includes chemical mechanical polishing (CMP) and/or etching back.

In an embodiment in which the first peripheral region 402 is an N-type MOSFET element region, the first liner 208, the third liner 211, and the filling layer 212 are silicon oxide layers, and the second liner 210 is a silicon nitride layer, the third liner 211 may be used to replace a portion of the second liner 210 adjacent the isolation features 206-1, 206-2 of the first peripheral region 402. In some embodiments, the third liner 211 formed of silicon oxide has intrinsic compressive stress, which can apply tensile stress to the adjacent first peripheral region 402 (such as the channel region of the N-type MOSFET), thereby increasing electron mobility in the channel region of the N-type MOSFET. When the size of N-type MOSFET elements is shrunk, the threshold voltage (Vt) roll-off phenomenon of the elements can be suppressed. In addition, in an embodiment in which the array region 400 is a DRAM array area and the second peripheral region 404 is a P-type MOSFET device region, the first liners 208, the second liners 210 and the filling layers 212 of the isolation features adjacent to the array region 400 or the second peripheral region 404 maintain the composite structure of silicon oxide-silicon nitride-silicon oxide, which may maintain the stresses in the array region 400 and the second peripheral region 404 and electrical performances (such as threshold voltage) of the memory array (such as a DRAM array) and the second-type component (such as a P-type MOSFET).

As shown in FIG. 1, the third liners 211 of the isolation features 206-1, 206-2 have bottom surfaces 211-B close to the bottom surfaces 204-1B, 204-2B of the trenches 204-1, 204-2. In some embodiments, the depth D1 from the bottom surfaces 204-1B and 204-2B of the trenches 204-1 and 204-2 to the top surface 200T of the substrate 200 is greater than the distance D2 from the bottom surface 211-B of the third liner 211 to the top surface 200T of the substrate 200. In some embodiments, the ratio of depth D2 to depth D1 may be within a range of about 1.3:2 to about 1.3:7. If the ratio of depth D2 to depth D1 is less than 1.3:7, the depth of the third liner 211 may be too small to apply sufficient compressive stress to the first peripheral region 402. If the ratio of depth D2 to depth D1 is greater than 1.3:2, the depth of the third liner 211 may exceed the depth D1 of the trenches 204-1 and 204-2 (for example, the ratio of the depth D2 to the depth D1 is greater than 1:1), which is not allowed by the manufacturing process.

The memory array 410 is formed in array region 400. The memory cell of memory array 410 may include a word line 230, contact plugs 248a, 248b, a bit line 250, and a storage capacitor 260. The word line 230 is embedded in the word line trench (not shown) of the substrate 200 in the array region 400 and extends across the active region A1 and the isolation feature 206-3. Furthermore, the word line 230 is disposed in the first well region 201.

The storage capacitor 260 of the memory array 410 is disposed above the substrate 200 and the contact plug 248b, and is electrically connected to the doped region 205b by the contact plug 248b.

One or more first-type components 412N are formed in the active region A2 of the first peripheral region 402. The first-type component 412N, such as an N-type MOSFET, may include a first gate structure 424N and first source/drain regions 428N. The first gate structure 424N is disposed on the substrate 200 in the second well region 202.

The first source/drain regions 428N of the first-type component 412N are disposed in the substrate 200 and adjacent to the opposite sides of the first gate structure 424N. The first source/drain region 428N has a bottom surface 428NB. In some embodiments, the depth D3 form the bottom surface 428NB of the first source/drain region 428N to the top surface 200T of the substrate 200 is less than or equal to the depth D2. If the depth D3 of the first source/drain region 428N is greater than the depth D2 of the third liner 211, the third liner 211 may not be able to apply the compressive stress to the whole channel region of the first-type component 412N (a portion of the active region A2 located below the first gate structure 424N and between the first source/drain regions 428N).

One or more second-type components 412P are formed in the active region A3 of the second peripheral region 404. The second-type component 412P, such as a P-type MOSFET, may include a second gate structure 424P and second source/drain regions 428P. The second gate structure 424P is disposed on the substrate 200 in the third well region 203. The first source/drain regions 428N and the second source/drain regions 428P have dopants of opposite conductivity types.

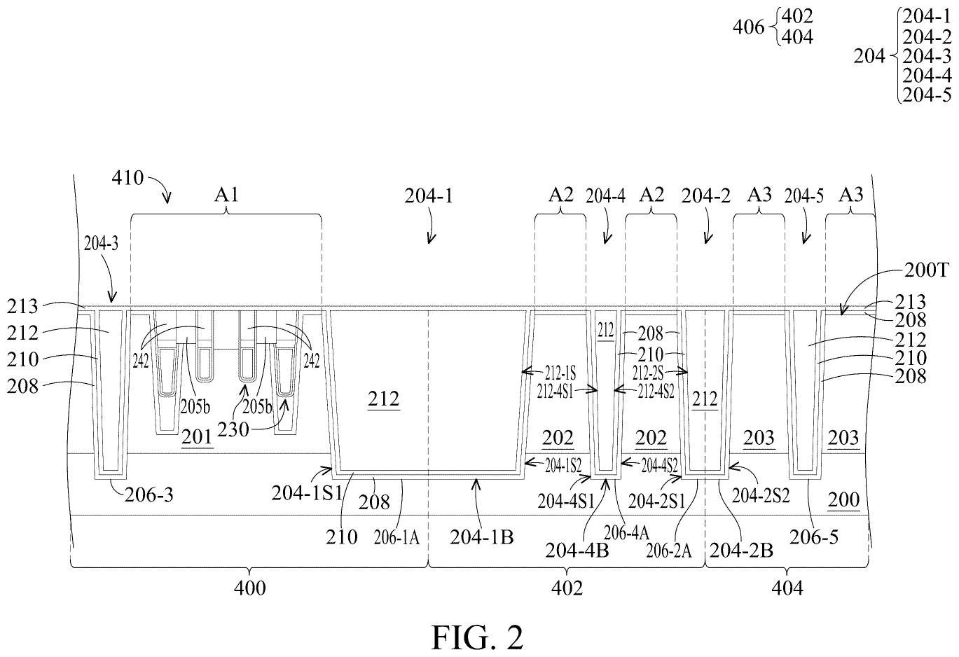

The method for forming the semiconductor structure 500 is described as follow using FIGS. 2 to 9. Refer to FIG. 2, a substrate 200 is provided. Next, multiple ion implantation processes are performed to implant a first dopant of a first conductivity type (e.g., P-type) into the substrate 200 in the array region 400 and the adjacent first peripheral region 402, and to implant a second dopant of a second conductivity type (e.g., N-type) into the substrate 200 in the second peripheral region 404. Therefore, a first well region 201 is formed in the substrate 200 in the array region 400, a second well region 202 is formed in the substrate 200 in the first peripheral region 402, and the third well region 203 is formed in the substrate 200 in the second peripheral region 404. Furthermore, a dopant of the second conductivity type opposite to the first conductivity type is implanted in the substrate 200 in the array region 400 to form a doping region 205b on the first well region 201.

Next, a patterning process is performed to form a plurality of trenches 204 in the substrate 200 to define the formation positions of the isolation features 206. Specifically, the patterning process forms a trench 204-1 in the substrate 200 between the array region 400 and the first peripheral region 402, forms a trench 204-2 in the substrate 200 between the first peripheral region 402 and the second peripheral region 404, forms a trench 204-3 in the substrate 200 in the array region 400, forms a trench 204-4 formed in the substrate 200 in the first peripheral region 402, and forms a trench 204-5 is in the substrate 200 in the second peripheral region 404.

Then, a deposition process and a subsequent planarization process are performed to form insulating structures and isolation features in the trenches 204. Specifically, the deposition process and planarization process respectively form insulating structures 206-1A, 206-2A, an isolation feature 206-3, an insulating structure 206-4A and an isolation feature 206-5 in the trenches 204-1, 204-2, 204-3, 204-4 and 204-5. Each of the insulation structures 206-1A, 206-2A, and 206-4A and isolation features 206-3 and 206-5 includes a first liner 208, a second liner 210, and a filling layer 212. The first liners 208 extend downward from the top surface 200T of the substrate 200 to conformally cover the bottom surfaces and opposite sidewalls of trenches 204-1, 204-2, 204-3, 204-4, and 204-5. Furthermore, the first liners 208 extend to cover the top surface 200T of the substrate 200. The second liners 210 extend downward from the top surface 200T of the substrate 200, and conformally and completely cover surfaces of the first liners 208 in the trenches 204-1, 204-2, 204-3, 204-4, and 204-5. The filling layers 212 fill the trenches 204-1, 204-2, 204-3, 204-4, and 204-5, and completely cover the second liner 210 in the trenches 204-1, 204-2, 204-3, 204-4, and 204-5.

Next, multiple deposition processes and etching processes are performed to form the word line 230 and the insulating capping layer 242 in the active region A1 of the array region 400.

Next, a deposition process such as ALD is performed to entirely form an insulating capping layer 213 such as silicon nitride on the substrate 200, the insulating structures 206-1A, 206-2A, and 206-4A, and the isolation features 206-3 and 206-5. In some embodiments, the first liner 208 and the filling layer 212 are formed of a first material (such as silicon oxide), and the second liner 210 and the insulating capping layer 213 are formed of a second material (such as silicon nitride) (therefore, there may be no interface between the second liner 210 and the insulating capping layer 213). In addition, the first material is different from the second material.

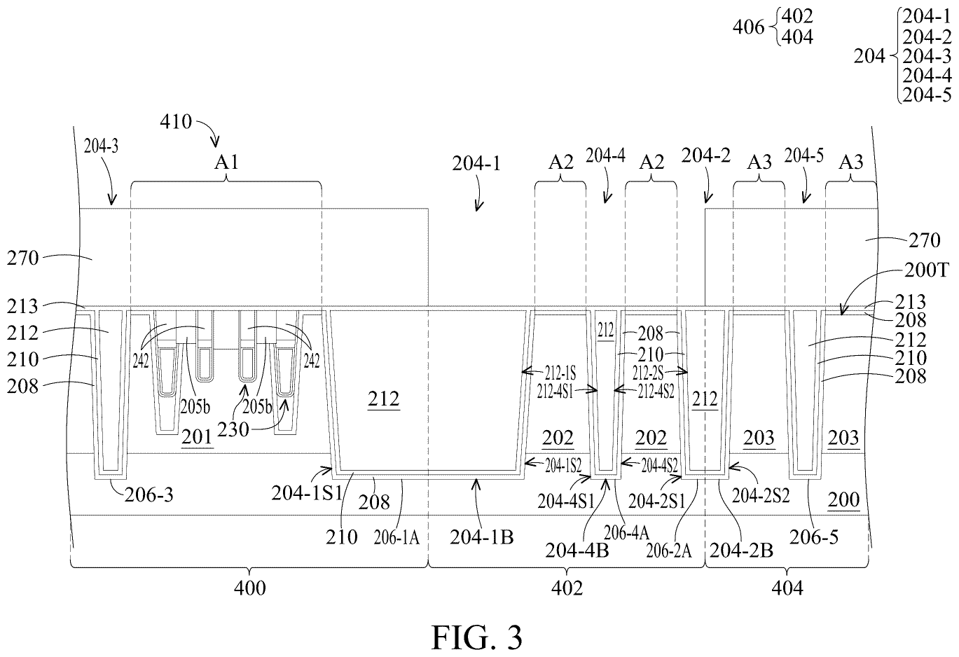

Next, as shown in FIG. 3, a lithography process is performed to form a photoresist pattern 270 on the top surface 200T of the substrate 200. The photoresist pattern 270 covers the array region 400 and the second peripheral region 404, exposing the insulating capping layer 213 in the first peripheral region. 402. The exposed insulating capping layer 213 covers portions of the insulating structures 206-1A and 206-2A adjacent to the sidewalls 204-1S2 and 204-2S1 of the trenches 204-1 and 204-2 as well as the insulating structure 206-4A in the first peripheral region 402.

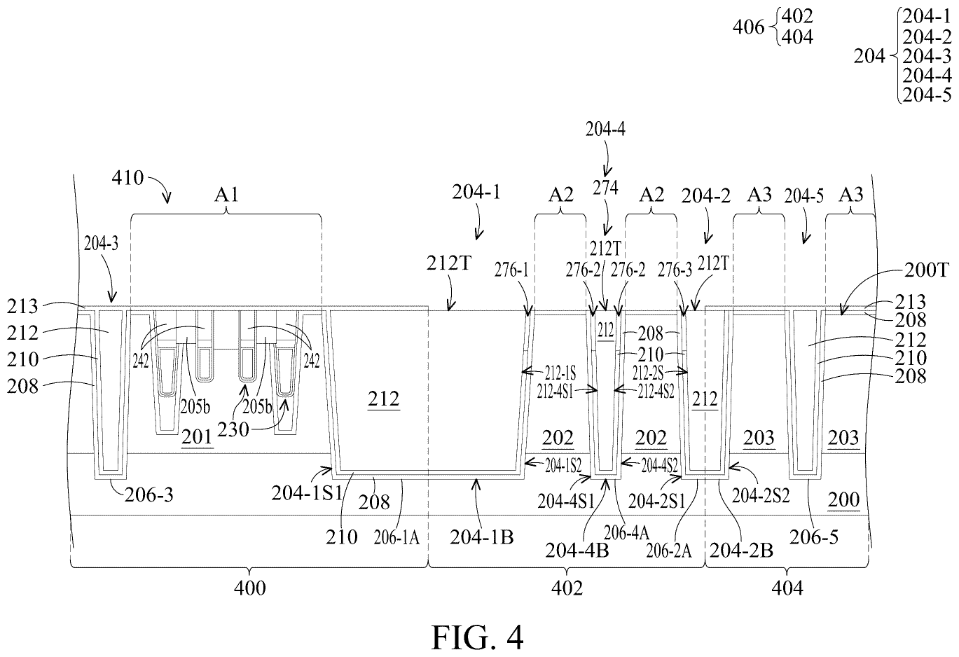

Next, as shown in FIG. 4, an etching process (e.g., wet etching) is performed on the exposed insulating capping layer 213 to remove a portion of the insulating capping layer 213 in the first peripheral region 402 using the photoresist pattern 270 as an etching mask. Since the insulating capping layer 213 and the second liner 210 include the same material, the aforementioned etching process may simultaneously remove portion of the second liner 210 on the upper portion of the insulating structures 206-1A, 206-2A close to the sidewalls 204-1S2, 204-2S1 of the trenches 204-1, 204-2, and remove a portion of the second liner 210 on the upper portion of the opposite sidewall of the insulating structure 206-4A close to the trench 204-4. After performing the aforementioned etching process, an opening 274 exposing the first peripheral region 402 is formed in the insulating capping layer 213, and openings 276-1, 276-2, 276-3 are formed in the insulating structures 206-1A, 206-2A, 206-4A. Therefore, the top surfaces 212T of the filling layers 212 of the insulating structures 206-1A, 206-2A, 206-4A, and first liners 208 and the filling layers 212 close to the upper portions of the sidewalls 204-1S2, 204-2S1 of the trenches 204-1, 204-2 and the opposite sidewalls 204-4S1, 204-4S2 of the trench 204-4 are exposed from the openings 276-1, 276-2, 276-3. The photoresist pattern 270 may be removed during the aforementioned etching process.

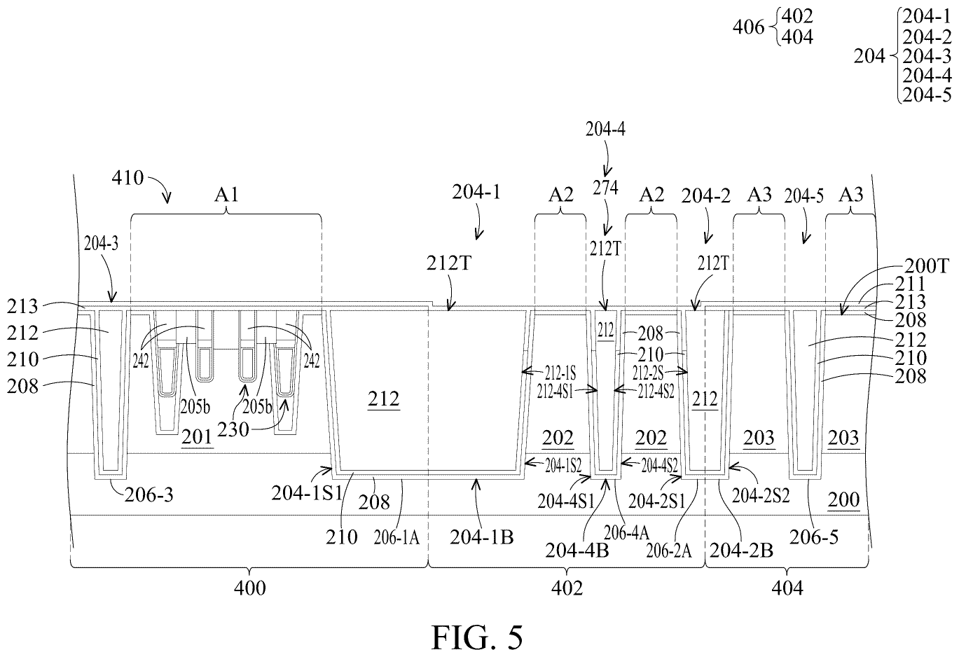

Next, as shown in FIG. 5, a deposition process such as ALD or sub-atmospheric pressure chemical vapor deposition (SACVD) is performed to entirely form the third liner 211. The third liner 211 covers the insulating capping layer 213 in the array region 400 and the second peripheral region 404. Moreover, the third liner 211 covers the active region A2 of the first peripheral region 402, the top surfaces 212T of the filling layers 212 of the insulating structures 206-1A, 206-2A, 206-4A, and fills the openings 274, 276-1, 276-2, 276-3 (FIG. 4).

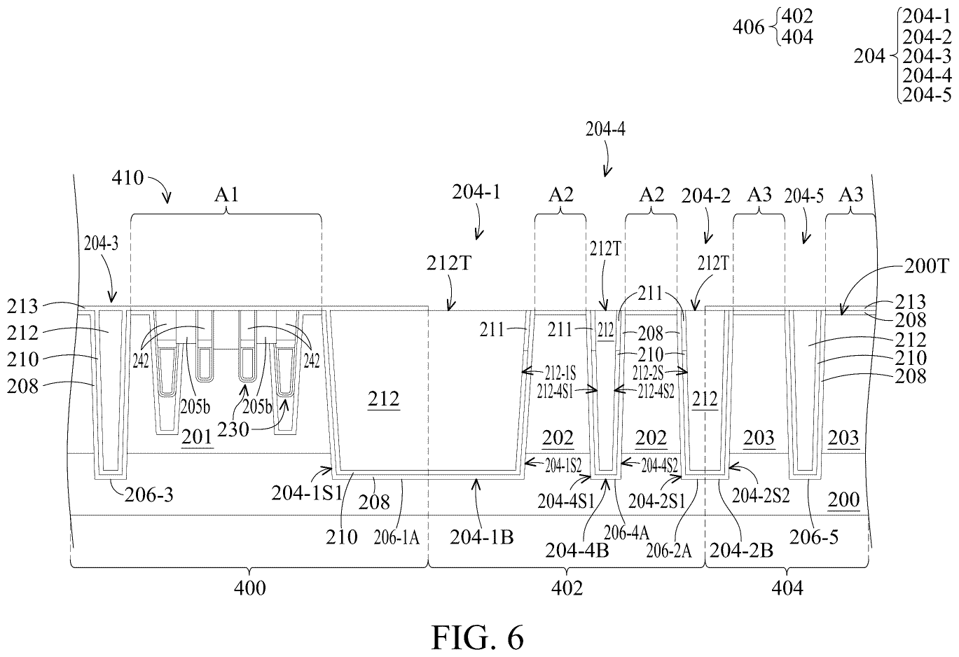

Next, as shown in FIG. 6, an etching process (e.g., dry etching or wet etching) is performed to remove the third liners 211 above the substrate 200. After the above etching process is performed, the remaining third liners 211 conformally cover the portions of the first liners 208 exposed from the second liners 210 of the insulating structures 206-1A, 206-2A, and 206-4A.

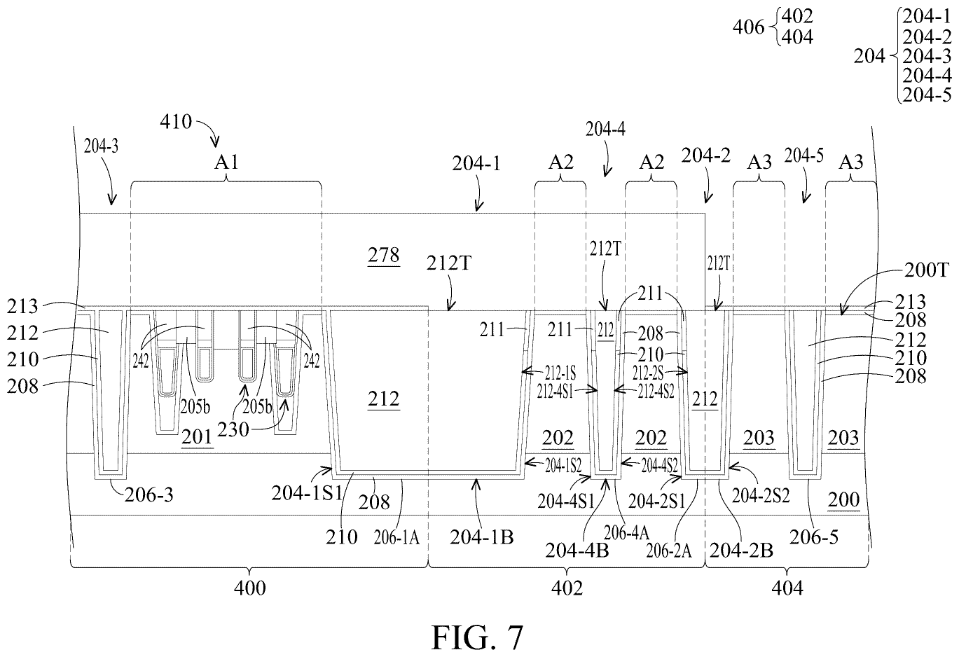

Next, as shown in FIG. 7, a photolithography process is performed to form a photoresist pattern 278 on the top surface 200T of the substrate 200. The photoresist pattern 278 covers the array region 400 and the first peripheral region 402, and exposes the insulating capping layer 213 in the second peripheral region 404.

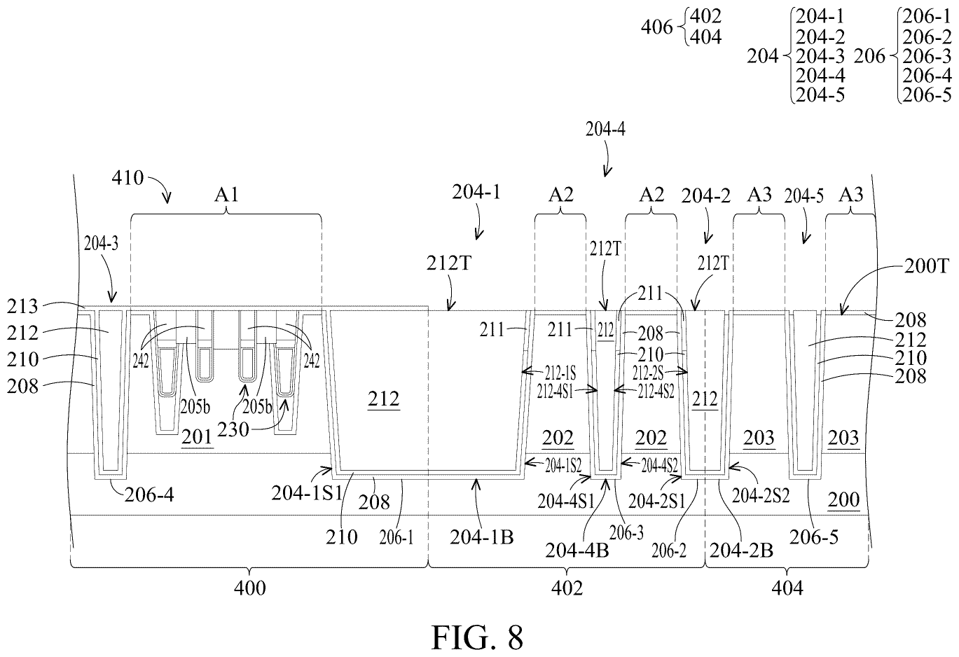

Next, as shown in FIG. 8, an etching process (e.g., wet etching) is performed on the exposed insulating capping layer 213 using the photoresist pattern 278 as an etching mask. The etching process removes a portion of the insulating capping layer 213 in the second peripheral region 404, so that the top surfaces 212T of the filling layers 212 of the insulating structure 206-2A and the isolation feature 206-5 are exposed. Furthermore, the remaining insulating capping layer 213 covers the array region 400. The photoresist pattern 278 may be removed during the etching process. After performing the aforementioned processes, the isolation features 206-1, 206-2, and 206-4 are formed in the trenches 204-1, 204-2, and 204-4.

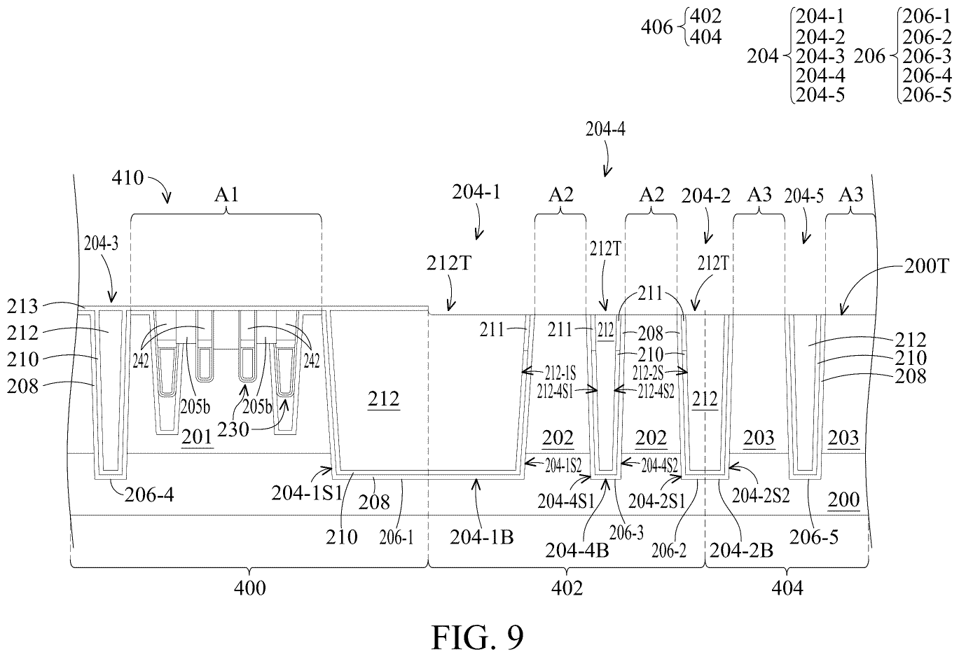

Next, as shown in FIG. 9, an etching back process (e.g., wet etching) is performed using the insulating capping layer 213 in the array region 400 as an etching mask. The etching back process removes the first liners 208 on the top surface 200T of the substrate 200 in the first peripheral region 402 and the second peripheral region 404, so that the top surface 200T of the substrate 200 in the active regions A2 and A3 is exposed.

Next, as shown in FIG. 1, a deposition process and subsequent lithography process and etching process are performed to form the first gate structure 424N and the second gate structure 424P on the substrate 200 in the first peripheral region 402 and the second peripheral region 404, respectively. Next, multiple ion implantation processes are performed to implant dopants of the second conductivity type (for example, N-type) into the substrate 200 adjacent to the opposite sides of the first gate structure 424N to form a plurality of first source/drain regions 428N. In addition, the multiple ion implantation processes are performed to implant dopants of the first conductivity type (for example, P-type) into the substrate 200 adjacent to the opposite sides of the second gate structure 424P to form a plurality of second source/drain regions 428P. After performing the aforementioned processes, the first-type component 412N and the second-type component 412P are formed in the first peripheral region 402 and the second peripheral region 404. In addition, a deposition process and a subsequent removal process (including a planarization process (e.g., CMP), an etching back process, or a combination thereof) may be performed to form contact plugs 248a, 248b, a bit line 250, and a storage capacitor 260 in the array region 400. After performing the aforementioned processes, the semiconductor structure 500 is formed.

Embodiments of the disclosure provide a semiconductor structure and a method for forming the same. The semiconductor structure includes an array region, a first peripheral region, a second peripheral region, and a first-type component (such as an N-type MOSFET element) and a second-type component (such as a P-type MOSFET element) which are used to form a memory array (such as a DRAM array) and having different conductivity types. In the isolation feature adjacent to or located within the first peripheral region, a third liner, such as a silicon oxide layer, may be used to replace a portion of the second liner, such as a silicon nitride layer, located between the first liner and the filling layer such as silicon oxide layers. Therefore, portions of the isolation features adjacent to the first peripheral region or located in the first peripheral region and close to the top surface of the substrate are formed of silicon oxide having compressive stress. The portions of the isolation features formed of silicon oxide may apply tensile stress to the adjacent first peripheral region (such as the channel region of the N-type MOSFET), thereby increasing the electron mobility in the N-type MOSFET. When the size of the first-type component (for example, N-type MOSFET) in the first peripheral region is scaled down, the Vt roll-off phenomenon may be suppressed. In addition, the first liner, the second liner, and the filling layer of the isolation feature adjacent to the array area or the second peripheral region may maintain the composite structure of silicon oxide-silicon nitride-silicon oxide. The stress in the array region and the second peripheral region and the electrical performances (such as threshold voltage) of the memory array (such as a DRAM array) and the second-type components (such as a P-type MOSFET) may be maintained.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a substrate having a first peripheral region;
a first isolation feature disposed in a first trench of the substrate adjacent to the first peripheral region, wherein the first trench has a first sidewall adjacent to the first peripheral region, wherein the first isolation feature comprises:
a first liner conformally covering the first sidewall of the first trench;
a second liner conformally covering the first liner, wherein the second liner covers a lower portion of the first sidewall so that a portion of the first liner is exposed from the second liner;
a third liner conformally covering the portion of the first liner exposed from the second liner; and
a filling layer filling the first trench and covering the second liner and the third liner; and
a first-type component formed in the first peripheral region, wherein in a direction that is substantially perpendicular to a top surface of the substrate, a first bottom surface of a first source/drain region of the first-type component is located between the top surface of the substrate and a second bottom surface of the third liner.

2. The semiconductor structure as claimed in claim 1, wherein the substrate has an array region or a second peripheral region adjacent to the first peripheral region, and the first trench has a second sidewall adjacent to the array region or the second peripheral region, wherein in the first isolation feature:
the first liner conformally covers the second sidewall of the first trench,
the second liner extends from the lower portion of the first sidewall of the first trench to cover the second sidewall.

3. The semiconductor structure as claimed in claim 1, wherein the first liner, the third liner, and the filling layer are formed of a first material, wherein the second liner is formed of a second material, and the first material is different from the second material.

4. The semiconductor structure as claimed in claim 3, wherein the first material comprises silicon oxide and the second material comprises silicon nitride.

5. The semiconductor structure as claimed in claim 1, wherein a first depth from the first bottom surface to the top surface of the substrate is less than or equal to a second depth from the second bottom surface to the top surface of the substrate.

6. The semiconductor structure as claimed in claim 5, wherein the first trench has a third bottom surface, and the second depth is less than or equal to a third depth from the third bottom surface to the top surface of the substrate.

7. The semiconductor structure as claimed in claim 6, wherein a ratio of the second depth to the third depth is within a range of 1.3:2 to 1.3:7.

8. The semiconductor structure as claimed in claim 1, wherein the first liner, the second liner, and the filling layer are in contact with different surfaces of the third liner

9. The semiconductor structure as claimed in claim 1, wherein a side surface of the filling layer close to the first sidewall of the first trench is in contact with the second liner and the third liner.

10. The semiconductor structure as claimed in claim 6, wherein an interface between the second liner and the third liner is located between the top surface of the substrate and the third bottom surface of the first trench.

11. The semiconductor structure as claimed in claim 5, wherein the semiconductor structure further comprises:
a second isolation feature disposed in a second trench of the substrate in the first peripheral region, wherein the second trench has a third sidewall and a fourth sidewall opposite each other,
wherein each of the first isolation feature and the second isolation feature comprises the first liner, the second liner, the third liner, and the filling layer,
wherein in the second isolation feature:
the first liner conformally covers the third sidewall and the fourth sidewall of the second trench,
the second liner conformally covers a portion of the first liner, and extends from a lower portion of the third sidewall of the second trench to cover a lower portion of the fourth sidewall, so that the portion of the first liner is exposed from the second liner,
the third liner conformally covers the first liner exposed from the second liner, and
the filling layer fills the second trench and covers the second liner and the third liner.

12. The semiconductor structure as claimed in claim 1, wherein the first-type component further comprises a first gate structure disposed on the substrate, wherein the first source/drain region is adjacent to the first gate structure.

13. The semiconductor structure as claimed in claim 2, further comprising:
a second-type component formed in the second peripheral region, wherein the first-type component and the second-type component have opposite conductivity types.

14. The semiconductor structure as claimed in claim 13, wherein the conductivity type of the first-type component is N-type, and the conductivity type of the second-type component is P-type.

15. A method for forming a semiconductor structure, comprising:
providing a substrate, wherein the substrate has a first peripheral region;
forming a first trench in the substrate adjacent to the first peripheral region, wherein the first trench has a first sidewall adjacent to the first peripheral region;
forming a first isolation feature in the first trench, wherein the first isolation feature comprises:
a first liner conformally covering the first sidewall of the first trench;
a second liner conformally covering the first liner, wherein the second liner covers a lower portion of the first sidewall, so that a portion of the first liner is exposed from the second liner;
a third liner conformally covering the portion of the first liner exposed from the second liner; and
a filling layer filling the first trench and covering the second liner and the third liner; and
forming a first-type component in the first peripheral region, wherein in a direction substantially perpendicular to a top surface of the substrate, a first bottom surface of a first source/drain region of the first-type component is located between the top surface of the substrate and a second bottom surface of the third liner.

16. The method for forming a semiconductor structure as claimed in claim 15, wherein the substrate has an array region or a second peripheral region adjacent to the first peripheral region, and the first trench has a second sidewall adjacent to the array region or the second peripheral region, wherein in the first isolation feature:
the first liner conformally covers the second sidewall of the first trench,
the second liner extends from the lower portion of the first sidewall of the first trench to cover the second sidewall.

17. The method for forming a semiconductor structure as claimed in claim 15, wherein forming the first isolation feature comprises:
forming a first insulation structure in the first trench, wherein the first insulation structure comprises the first liner, the second liner, and the filling layer, and the second liner completely covers the first liner in the first trench;
forming a first insulating capping layer on the substrate and the first insulating structure;
removing a portion of the first insulating capping layer in the first peripheral region, and removing a portion of the second liner close to the first sidewall from the top surface of the substrate to form a first opening in the first insulating structure, so that a top surface and an upper portion of the filling layer in the first insulation structure are exposed from the first opening, wherein the upper portion of the filling layer is close to a side surface of the first sidewall;
entirely forming a third liner, wherein the third liner covers the filling layer and fills the first opening; and
removing the third liner above the substrate to form the first isolation feature in the first trench.

18. The method for forming a semiconductor structure as claimed in claim 17, further comprising:
forming a second trench in the substrate in the first peripheral region during the formation of the first trench, wherein the second trench has a third sidewall and a fourth sidewall opposite each other; and
forming a second isolation feature in the second trench during the formation of the first isolation feature, wherein forming the second isolation feature comprises:
forming a second insulation structure in the second trench during the formation of the first insulation structure, wherein each of the first insulation structure and the second insulation structure comprises the first liner, the second liner, and the filling layer, wherein removing the portion of the second liner comprises:
removing the portion of the second liner close to the third sidewall and the fourth sidewall of the second trench from the top surface of the substrate to form second openings in the second isolation feature, so that a top surface and upper portions of the filling layer in the second insulation structure are exposed from the second openings, wherein the upper portions of the filling layer are close to the third sidewall and the fourth sidewall.

19. The method for forming a semiconductor structure as claimed in claim 18, wherein the second isolation feature is formed in the second trench after removing the third liner above the substrate.

20. The method for forming a semiconductor structure as claimed in claim 15, wherein forming the first-type component comprises;
forming a first gate structure on the substrate; and
forming the first source/drain region in the substrate adjacent to the first gate structure,
wherein the first source/drain region has a first bottom surface, the third liner has a second bottom surface close to the first bottom surface, and the first trench has a third bottom surface,
wherein a first depth from the first bottom surface to the top surface of the substrate is less than or equal to a second depth from the second bottom surface to the top surface of the substrate, and
wherein the second depth is less than or equal to a third depth from the third bottom surface to the top surface of the substrate.
